(19) United States
(12) Patent Application Publication
(10) Pub. No.: US 2009/0160690 A1
(43) Pub. Date: Jun. 25, 2009

(54) D/A CONVERTER CIRCUIT, INTEGRATED CIRCUIT DEVICE, AND ELECTRONIC APPARATUS

(75) Inventors: Kazuo KAWAGUCHI, Chino (JP); Teruhiko HAYASHI, Hachioji (JP); Kunihiro KAJIHARA, Suginami (JP)

Correspondence Address: HARNESS, DICKEY & PIERCE, P.L.C., P.O. BOX 828, BLOOMFIELD HILLS, MI, 48303, US

(73) Assignees: SEIKO EPSON CORPORATION, Tokyo (JP); SOLITON SYSTEMS K.K., Tokyo (JP)

(21) Appl. No.: 12/342,402

(22) Filed: Dec. 23, 2008

(30) Foreign Application Priority Data
Dec. 25, 2007 (JP) 2007-331871

(51) Int. Cl. H03M 1/78

(52) U.S. Cl. 341/154

(57) ABSTRACT

A D/A converter circuit which converts a digital signal of n bits into an analog signal and outputs the analog signal comprises: a plurality of D/A conversion processors, each of which converting a digital signal into an analog signal, the digital signal being made by dividing the n-bit digital signal at least into two; a plurality of output resistance regulators coupled to outputs of the plurality of respective D/A conversion processors; and an output signal generator generating the analog signal that forms an output of the D/A converter circuit based on outputs of the plurality of output resistance regulators. At least one of the D/A conversion processors is configured as a resistor string type D/A converter circuit including: a resistor string circuit which has a plurality of serially-coupled resistors and a plurality of switches, one end of each of the plurality of switches being coupled to one of coupling points of the plurality of resistors, and other ends of the plurality of switches being coupled together to form an output end; and a decode circuit which decodes the digital signal and generates a control signal that controls ON/OFF of the plurality of switches included in the resistor string circuit. Each of the plurality of output resistance regulators includes a variable resistance circuit which changes a resistance value to be substantially equal to an output resistance value of the D/A conversion processor, in accordance with a change in the output resistance value of the D/A conversion processor that is coupled to another output resistance regulator and configured as the resistor string type D/A converter circuit.

Japanese Patent Application No. 2007-331871, filed on Dec. 25, 2007, is hereby incorporated by reference in its entirety.

### BACKGROUND

1. Technical Field

Several aspects of the present invention relate to a digital-to-analog (D/A) converter circuit, an integrated circuit device, and an electronic apparatus.

2. Related Art

Technical development for miniaturization of integrated circuits (ICs) entails demands for high-precision multi-bit D/A converter circuits that can be manufactured at low costs. For example, a 12-bit D/A converter circuit is required to have an accuracy of 1/4096. Various types of D/A converter circuits have been proposed, and, among them, a resistor string type D/A converter circuit and an R-2R resistor ladder type circuit are known. JP-A-2001-177410 and JP-A-11-127080 are examples of related art.

The resistor string type D/A converter circuit generates an output voltage by dividing a reference voltage in accordance with an input code using a plurality of serially coupled resistors. The conversion accuracy of ½ⁿ is thus secured even if a bit number n of a digital input signal is relatively large. However, because 2ⁿ number of resistors and 2ⁿ number of switches are needed corresponding to the bit number n, the layout area increases drastically as the bit number n increases. For example, if the resistor string type D/A converter circuit conducts the D/A conversion of 12 bits, 4096 resistors and 4096 switches are needed, and thus the cost reduction demands are not satisfied even though the bit number is increased. In contrast, with the R-2R resistor ladder type D/A converter circuit having resistors in a number proportional to the bit number n, the cost reduction requirements are satisfied even if the bit number n increases. However, taking into consideration the variations that occur during the manufacture of the R-2R resistor ladder type D/A converter circuit by a complementary metal-oxide semiconductor (CMOS) process, the conversion accuracy of ½ⁿ may not be secured if the bit number n increases because of the structure of the R-2R resistor ladder type D/A converter circuit. Thus, it is extremely difficult to realize the D/A conversion of 12 bits, for example, using the R-2R resistor ladder type D/A converter circuit.

### SUMMARY

An advantage of the invention is to provide a D/A conversion circuit applicable to D/A conversion of a relatively large number of bits using a relatively small layout area.

According to a first aspect of the invention, a D/A converter circuit which converts a digital signal of n bits into an analog signal and outputs the analog signal includes: a plurality of D/A conversion processors, each of which converting a digital signal into an analog signal, the digital signal being made by dividing the n-bit digital signal at least into two; a plurality of output resistance regulators coupled to outputs of the plurality of respective D/A conversion processors; and an output signal generator generating the analog signal that forms an output of the D/A converter circuit based on outputs of the plurality of output resistance regulators, in that: at least one of the D/A conversion processors is configured as a resistor string type D/A converter circuit including: a resistor string circuit which has a plurality of serially-coupled resistors and a plurality of switches, one end of each of the plurality of switches being coupled to one of coupling points of the plurality of resistors, and other ends of the plurality of switches being coupled together to form an output end; and a decode circuit which decodes the digital signal and generates a control signal that controls ON/OFF of the plurality of switches included in the resistor string circuit, and in that each of the plurality of output resistance regulators includes a variable resistance circuit which changes a resistance value to be substantially equal to an output resistance value of the D/A conversion processor, in accordance with a change in the output resistance value of the D/A conversion processor that is coupled to another output resistance regulator and configured as the resistor string type D/A converter circuit.

The resistance value substantially equal to the output resistance value, although different it may be from the output resistance value, may be within the range of error that does not affect conversion accuracy of ½ⁿ.

Because the highest conversion accuracy (with conversion error of no more than ½ⁿ) is required of the D/A conversion processor that carries out the D/A conversion of the digital signal containing the most significant bit out of the n bits, it is preferable to configure the resistor string type D/A converter circuit if the bit number n is relatively large.

In this aspect of the invention, the plurality of D/A conversion processors convert respective digital signals into respective analog signals, the digital signals being made by dividing the n-bit digital signal at least into two. If a bit number to be converted by the D/A conversion processors is relatively small, the layout area may be made small even if the D/A converter circuit is configured as the resistor string type. Also, even if the bit number n is relatively large, it is possible to secure the ½ⁿ of conversion accuracy by configuring the D/A converter circuit as the resistor string type that converts the digital signal containing the most significant bit. Therefore, according to this aspect of the invention, it is possible to provide a D/A conversion circuit applicable to D/A conversion of a relatively large number of bits using a relatively small layout area.

Also, according to this aspect of the invention, each of the output resistance regulators includes the variable resistance circuit that changes the resistance value to be substantially equal to the output resistance of the D/A conversion processor that is configured as the resistor string type D/A converter circuit. Specifically, although the output resistance of the resistor string type D/A converter circuit fluctuates in accordance with the input code, it is possible to cancel this fluctuation by generating the analog signal as an output of the D/A converter circuit based on the outputs of the output resistance regulators containing the variable resistance circuits. It is thus possible to suppress deterioration in D/A conversion accuracy due to the fluctuation of the output resistance of the resistor string type D/A converter circuit.

With the D/A converter circuit of the first aspect of the invention, it is preferable that the output signal generator include a circuit that couples the outputs of the plurality of output resistance regulators.

In this case, by connecting the outputs of the output resistance regulators, the divided signals may be outputted without using operational amplifiers that add up the outputs of the plurality of output resistance regulators. It is therefore possible to suppress increase of electric consumption and layout area.

With the D/A converter circuit of the first aspect of the invention, it is preferable that: a first one of the plurality of D/A conversion processors be configured as the resistor string type D/A converter circuit that converts a digital signal of upper p bits, out of the n bits, into an analog signal; a second one of the plurality of D/A conversion processors convert a digital signal of lower q bits (q=n−p), out of the n bits, into an analog signal; and a second one of the plurality of output resistance regulators which is coupled an output of to the second D/A conversion processor includes the variable resistance circuit that changes a resistance value to be substantially equal to an output resistance value of the first D/A conversion processor, in accordance with a change in the output resistance value of the first D/A conversion processor.

In this case, the resistance value substantially equal to the output resistance value, although different it may be from the resistance value, may be within the range of error that does not affect the conversion accuracy of ½ⁿ.

Also, the first D/A conversion processor configured as the resistor string type D/A converter circuit performs conversion of the upper p bits, out of the n-bit digital signal which has been divided into two. Thus, although the D/A conversion of the upper p bits requires the conversion accuracy of ½ⁿ, this accuracy may be secured if the conversion is performed by the resistor string type D/A converter circuit.

Also, the second output resistance regulator coupled to the second D/A conversion processor converting the lower q bits includes the variable resistance circuit which changes the resistance to be substantially equal to the output resistance of the first conversion processor (the resistor string type D/A converter circuits). It is therefore possible to suppress the deterioration in D/A conversion accuracy due to fluctuation of the output resistance of the resistor string type D/A converter circuit.

With the D/A converter circuit of the first aspect of the invention, it is preferable that the variable resistance circuit of the second output resistance regulator have a same configuration as that of the resistor string circuit of the first D/A conversion processor.

In this case, because the variable resistance circuit of the second output resistance regulator has the same configuration as that of the resistor string circuit of the first D/A conversion processor, the resistance of the second output resistance regulator may readily be the same as the output resistance of the first D/A conversion processor.

Also, because the variable resistance circuit of the second output resistance regulator has the same configuration as that of the resistor string circuit of the first D/A conversion processor, the same layout pattern may be used. Thus, the fluctuation of the resistance due to manufacturing variations may be cancelled, and it is possible to provide the D/A converter circuit with higher performance.

With the D/A converter circuit of the first aspect of the invention, it is preferable that: the second D/A conversion processor be configured as the resistor string type D/A converter circuit; and a first one of the plurality of output resistance regulators which is coupled to an output of the first D/A conversion processor includes the variable resistance circuit that changes a resistance value to be substantially equal to an output resistance value of the second D/A conversion processor, in accordance with a change in the output resistance value of the second D/A conversion processor.

In this case, the resistance value substantially equal to the output resistance value, although different it may be from this output resistance value, may be within the range or error that does not affect the conversion accuracy of ½ⁿ.

Also, not only the first D/A conversion processor but also the second D/A conversion processor is configured as the resistor string type D/A converter circuit. Thus, if the lower bit number q is relatively large, the second D/A conversion processor may secure the conversion accuracy of ½^{q}, and the conversion accuracy of ½ⁿ may be secured as a whole.

Also, the first output resistance regulator coupled to an output of the second D/A conversion processor includes the variable resistance circuit that changes the resistance value to be substantially equal to the value of the output resistance of the second D/A conversion processor (the resistor string type D/A converter circuit). It is therefore possible to suppress the deterioration in D/A conversion accuracy due to fluctuation of the output resistance value of the resistor string type D/A converter circuit.

With the D/A converter circuit of the first aspect of the invention, it is preferable that the variable resistance circuit of the first output resistance regulator have a same configuration as that of the resistor string circuit of the second D/A conversion processor.

In this case, because the variable resistance circuit of the first output resistance regulator has the same configuration as that of the resistor string circuit of the second D/A conversion processor, the resistance value of the first output resistance regulator may readily be substantially equal to the output resistance of the second D/A conversion processor.

Also, because the variable resistance circuit of the first output resistance regulator has the same configuration as that of the resistor string circuit of the second D/A conversion processor, the same layout pattern may be used. Therefore, because fluctuation of the resistance value due to manufacturing variations may be cancelled, it is possible to provide the D/A converter circuit with higher performance.

It is preferable that the D/A converter circuit of the first aspect of the invention further include: a reference voltage supply section which, by use of a first resistance voltage dividing circuit, generates substantially ½^{p} of a reference voltage supplied to the resistor string circuit of the first D/A conversion processor and supplies the voltage to the resistor string circuit of the second D/A conversion processor.

The reference voltage of substantially ½^{p}, although different it may be from the reference voltage of ½^{p}, may be within the range of error does not affect the conversion accuracy of ½ⁿ.

The first resistance voltage dividing circuit may be configured to include the same layout pattern as that of the plurality of (p number of) serially-coupled resistors included in the resistor string circuit of the first D/A conversion processor. For example, the first resistance voltage dividing circuit may divide the reference voltage into ½^{p} by using any p number of resistors having the same configuration as that of the mentioned p number of resistors. Alternatively, in addition to having any p number of resistors having the same configuration as that of the mentioned p number of resistors, the first resistance voltage dividing circuit may also have a configuration such that some of the p number of resistors are serially or parallelly coupled to another resistor. In the case of the latter, this resistor may be provided as a dummy resistor also in the layout pattern of the resistor string circuit of the first D/A conversion processor.

Also, the resistor string circuit of the second D/A conversion processor receives substantially ½^{p} of the reference voltage that is supplied to the resistor string circuit of the first D/A conversion processor. Therefore, the scale of the output voltage of the second D/A conversion processor may become substantially ½^{p} of the scale of the output voltage of the first D/A conversion processor. For this reason, it may not be necessary to provide circuits for adjusting the output voltage of the second D/A conversion processor.

With the D/A converter circuit of the first aspect of the invention, it is preferable that the first output resistance regulator further include a resistive circuit having a resistance value substantially equal to an output resistance value of the reference voltage supply section.

In this case, the resistance substantially equal to that of the output resistance of the reference voltage supply section, although different it may be from the output resistance of the reference voltage supply section, may be within the range of error does not affect the conversion accuracy of ½ⁿ.

Also, the output resistance of the second output resistance regulator as observed from the output signal generator becomes a combined output resistance of the second D/A conversion processor and the reference voltage supply section. According to the first aspect of the invention, the first output resistance regulator includes not only the variable resistance circuit that changes the resistance to be substantially equal to the output resistance of the second conversion processor, but also the resistive circuit having substantially the same resistance as the output resistance of the reference voltage supply section. Thus, the output resistance of the first output resistance regulator as observed from the output signal generator may be substantially equal to the output resistance of the second output resistance regulator. It is therefore possible to provide the D/A converter circuit with higher performance.

With the D/A converter circuit of the first aspect of the invention, it is preferable that the second D/A conversion processor be configured as an R-2R resistor ladder type D/A converter circuit including: a resistor ladder circuit having a resistor of a resistance value R and a resistor of a resistance value 2R that are connected in a ladder like fashion, and a switching circuit switching the connection of the resistor ladder circuit in accordance with the digital signal, and that the first output resistance regulator, which is coupled to an output of the first D/A conversion processor, include a resistive circuit having a resistance value substantially equal to an output resistance value of the second D/A conversion processor.

In this case, the resistance value substantially equal to that of the output resistance value of the second D/A conversion processor, although different it may be from the output resistance value of the second D/A conversion processor, may be within the range of error does not affect the conversion accuracy of ½ⁿ.

Also, the second D/A conversion processor is configured as the R-2R resistor ladder type D/A converter circuit. Therefore, in comparison to the second D/A conversion processor configured as the resistor string type D/A converter circuit, the layout area of the second D/A conversion processor may be reduced.

Also, the first output resistance regulator coupled to the output of the first D/A conversion processor includes the resistive circuit having substantially the same resistance value as the output resistance value of the second D/A conversion processor (the R-2R resistor ladder type D/A converter circuit). Therefore, the output resistance value of the R-2R resistor ladder type D/A converter circuit may be cancelled.

With the D/A converter circuit of the first aspect of the invention, it is preferable that the second D/A conversion processor include an output voltage regulating circuit which, by use of a second resistance voltage dividing circuit, generates substantially ½^{p} of an output voltage of the resistor ladder circuit and supplies the voltage to the second output resistance regulator.

In this case, the substantially ½^{p} of the output voltage of the resistor ladder circuit, although different it may be from the ½^{p} of the output voltage of the resistor ladder circuit, may be within the range of error does not affect the conversion accuracy of ½ⁿ.

Also, when substantially ½^{p} of the reference voltage supplied to the first D/A conversion processor is supplied to the second D/A conversion processor, the reference voltage to be supplied to the second D/A conversion processor decreases as the upper bit number p increases, and the switching circuits included in the second D/A conversion processor become inoperable. However, according to the first aspect of the invention, it is the output voltage regulating circuit that generates the substantially ½^{p} of the output voltage of the resistor ladder circuit and supplies the voltage to the second output resistance regulator. Accordingly, even if the upper bit number p increases, the second D/A conversion processor may carry out a normal D/A conversion process.

With the D/A converter circuit of the first aspect of the invention, it is preferable that p=q.

In this case, the first and second D/A conversion processors are configured such that the upper bit number p and the lower bit number q become the same (n/2). Therefore, for example, if the first and second D/A conversion processors are both configured as the resistor string type D/A converter circuits, they may have completely the same circuitry configuration. Furthermore, the configurations of the first and second output resistance regulators may also be the same as those of the first and second D/A conversion processors. Because the first and second D/A conversion processors and the first and second output resistance regulators may all have the same configuration, they may use the same layout pattern. Accordingly, the fluctuation of the resistance value due to the manufacturing variations may be cancelled, and it is therefore possible to provide the D/A converter circuit with higher performance.

Also, for example, if the first and second D/A conversion processors are both configured as the resistor string type D/A converter circuits, the number of resistors included in the first and second D/A conversion processors becomes 2^{p}+2^{q}, and, thus, the number of the resistors reaches its minimum when p=q =n/2. Therefore, even if the first and second D/A conversion processors are both configured as the resistor string type D/A converter circuits, it is possible to provide the D/A conversion circuit having the small layout area.

According to a second aspect of the invention, an integrated circuit device includes the D/A converter circuit of the first aspect of the invention.

According to a third aspect of the invention, an electronic apparatus includes: the integrated circuit device according to the second aspect of the invention, an input section that receives input information, and an output section that, based on the input information, outputs a result processed by the integrated circuit device.

### BRIEF DESCRIPTION OF THE DRAWINGS

The invention will be described with reference to the accompanying drawings, wherein like numbers reference like elements.

FIG. 1 is a block diagram of a D/A converter circuit according to one embodiment of the invention.

FIG. 2 is a diagram exemplarily showing an equivalent circuit of the D/A converter circuit.

FIG. 3 is a diagram to explain an exemplary configuration of the D/A conversion processor.

FIG. 4 is a truth table of an m-bit decoder.

FIG. 5 is a diagram to explain an exemplary configuration of the D/A conversion processor.

FIG. 6 is an exemplary functional block diagram of an output resistance regulator.

FIGS. 7A and 7B are diagrams showing exemplary configurations of resistive circuits of the output resistance regulators.

FIG. 8 is a diagram to explain the configuration of a first exemplary D/A converter circuit according to the embodiment of the invention.

FIG. 9A is a diagram exemplarily showing an equivalent circuit of an upper bit output resistance regulating circuit.

FIG. 9B is a diagram exemplarily showing an equivalent circuit of an output resistance of a lower bit D/A converter circuit and an output resistance of a reference voltage generating circuit.

FIG. 10 is a diagram to explain the configuration of a second exemplary D/A converter circuit according to the embodiment of the invention.

FIG. 11 is an exemplary block diagram of an integrated circuit device according to one embodiment of the invention.

FIG. 12 is an exemplary block diagram of an electronic apparatus including the integrated circuit device.

FIGS. 13A through 13C are external views of various examples of the electronic apparatus.

### DESCRIPTION OF EXEMPLARY EMBODIMENTS

Embodiments of the invention will now be described with reference to the drawings. The embodiments described below should not unduly limit the content of the present invention as stated in the claims. Also, not all the structures described hereafter are necessarily the essential elements of the invention.

1. Configuration of Digital-to-Analog (D/A) Converter Circuit

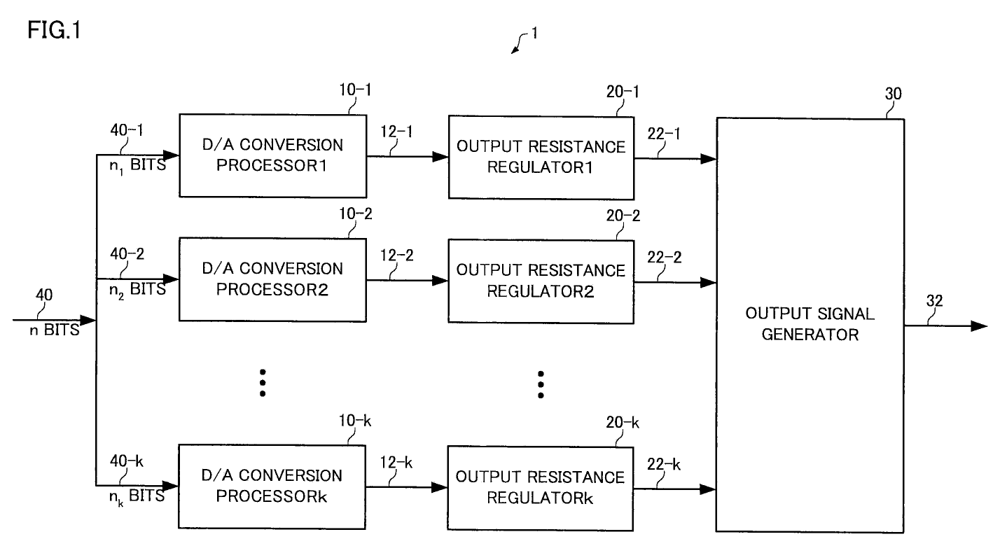

FIG. 1 is a block diagram of the D/A converter circuit according to one embodiment of the invention.

A D/A converter circuit 1 converts an n-bit digital signal 40 to an analog signal 32 and outputs the analog signal 32.

The D/A converter circuit 1 includes: a k number (k≧2) of D/A conversion processors (D/A conversion processors 1 to k (10-1 to 10-k)), a k number of output resistance regulators (output resistance regulators 1 to k (20-1 to 20-k)), and an output signal generator 30. The output resistance regulators 1 to k (20-1 to 20-k) are coupled to outputs of the respective D/A conversion processors 1 to k (10-1 to 10-k), and the output signal generator 30 is coupled to the output resistance regulators 1 to k (20-1 to 20-k).

The D/A conversion processors 1 to k (10-1 to 10-k) convert respective n₁- to nₖ-bit digital signals 40-1 to 40-k, which are made by dividing the n-bit digital signal 40 at least into two, to respective analog signals 12-1 to 12-k. At least one of the D/A conversion processors 1 to k (10-1 to 10-k) is configured as a resistor string type D/A converter circuit.

Each of the output resistance regulators 1 to k (20-1 to 20-k) includes a variable resistance circuit which changes a resistance values to be substantially equal to the output resistance value of the D/A conversion processor, in accordance with a change in this output resistance value of the D/A conversion processor which is coupled to another output resistance regulator and configured as the resistor string type D/A converter circuit. The output resistance of the resistor string type D/A converter circuit fluctuates in accordance with an input code. However, because the output resistance regulators 1 to k (20-1 to 20-k) include the variable resistance circuits and thereby cancel the fluctuation of the output resistance as a result, it is possible to suppress the deterioration in D/A conversion accuracy.

For example, if the D/A conversion processor 1 (10-1) is configured as the resistor string type D/A converter circuit, each of the output resistance regulators 2 to k (20-2 to 20-k) is configured to include a variable resistance circuit that changes a resistance value, in accordance with a change in the output resistance value of the D/A conversion processor 1 (10-1), to be substantially equal to this output resistance value. Also, for example, if the D/A conversion processors 1, 2 (10-1, 10-2) are configured as the resistor string type D/A converter circuits, then: the output resistance regulator 1 (20-1) is configured to include a variable resistance circuit that changes a resistance value, in accordance with a change in the output resistance value of the D/A conversion processor 2 (10-2), to be substantially equal to this output resistance value; the output resistance regulator 2 (20-2) is configured to include a variable resistance circuit that changes a resistance value, in accordance with a change in the output resistance value of the D/A conversion processor 1 (10-1), to be substantially equal to this output resistance value; and each of the output resistance regulators 3 to k (20-3 to 20-k) includes a variable resistance circuit that changes a resistance value, in accordance with changes in the output resistance values of the D/A conversion processors 1, 2 (10-1, 10-2), to be substantially equal to these output resistance values.

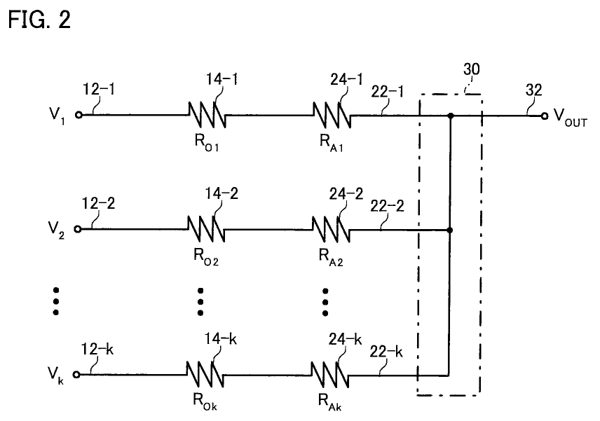

The output signal generator 30 generates the analog signal 32, which becomes an output of the D/A converter circuit 1, based on outputs of the output resistance regulators 1 to k (20-1 to 20-k). The output signal generator 30 may include a circuit that connects the outputs of the output resistance regulators 1 to k (20-1 to 20-k). FIG. 2 shows an equivalent circuit of the D/A converter circuit 1 in which output signals 22-1 to 22-k of the output resistance regulators 1 to k (20-1 to 20-k) are connected. Referring to the equivalent circuit of FIG. 2, V₁ to Vₖ indicate voltages of the respective output signals 12-1 to 12-k of the D/A conversion processors 1 to k (10-1 to 10-k). Resistors 14-1 to 14-k are output resistors (resistance values R_{O1} to R_{Ok}, respectively) of the D/A conversion processors 1 to k (10-1 to 10-k), and resistors 24-1 to 24-k are internal resistors (resistance values R_{A1} to R_{Ak}, respectively) of the output resistance regulators 1 to k (20-1 to 20-k). V_{OUT} is a value of voltage of the output signal 32 of the D/A converter circuit 1.

The equivalent circuit with reference to FIG. 2, when applied to the Kirchhoff's laws, is expressed by a formula: (V₁−V_{OUT})/(R_{O1}+R_{A1})+(V₂−V_{OUT})/(R_{O2}+R_{A2})+ . . . +(Vₖ−V_{OUT})/(R_{Ok}+R_{Ak})=0. In this regard, when the resistance values R_{A1} to R_{Ak} are set as R_{O1}+R_{A1}=R_{O2}+R_{A2}= . . . =R_{Ok}+R_{Ak}=R_{O} (constant value), a formula (V₁−V_{OUT})/R_{O}+(V₂−V_{OUT})/R_{O}+ . . . +(Vₖ−V_{OUT})/R_{O}=0 is given, and therefore V_{OUT}=(V₁+V₂+ . . . +Vₖ)/k. In other words, by adding up the output voltages V₁ to Vₖ of the D/A conversion processors 1 to k (10-1 to 10-k), the output voltage V_{OUT} of the D/A converter circuit 1 is produced. Therefore, the n-bit D/A converter circuit is obtained if the D/A conversion processors 1 to k (10-1 to 10-k) are configured such that the scale of Vⱼ (j =2 to k) becomes ½^{(n1+ . . . +nj-1)} of the scale of V₁.

Referring to FIG. 1, the D/A converter circuit 1 may conduct the n-bit D/A conversion (i.e., a case where k=2) using two D/A conversion processors (D/A conversion processors 1, 2 (10-1, 10-2)). In this case, the D/A conversion processor 1 (10-1) operates as a first D/A conversion processor, and the D/A conversion processor 2 (10-2) operates as a second D/A conversion processor. Also, the output resistance regulator 1 (20-1), which is coupled to an output of the D/A conversion processor 1 (10-1), operates as a first output resistance regulator. Similarly, the output resistance regulator 2 (20-2), which is coupled to an output of the D/A conversion processor 2 (10-2), operates as a second output resistance regulator.

The D/A conversion processor 1 (10-1) may be configured as the resistor string type D/A converter circuit that converts the digital signal 40-1 of upper p bits, out of the n bits (i.e., n₁=p), into the analog signal 12-1. In this case, the output resistance regulator 2 (20-2) may include the variable resistance circuit that changes the resistance value to be substantially equal to the output resistance value of the D/A conversion processor 1 (10-1) in accordance with a change in this output resistance value. This variable resistance circuit may have the same configuration as that of the resistor string circuit of the D/A conversion processor 1 (10-1).

The D/A conversion processor 2 (10-2) converts the digital signal 40-2 of lower q bits (q=n−p), out of n bits (i.e., n₂=q), into the analog signal 12-2.

The D/A conversion processor 2 (10-2) may be configured as the resistor string type D/A converter circuit. In this case, the output resistance regulator 1 (20-1) may include the variable resistance circuit that changes the resistance value to be substantially equal to the output resistance value of the D/A conversion processor 2 (10-2) in accordance with a change in this output resistance value. This variable resistance circuit may have the same configuration as that of the resistor string circuit of the D/A conversion processor 2 (10-2).

Alternatively, the D/A conversion processor 2 (10-2) may be configured as an R-2R resistor ladder type D/A converter circuit. In this case, the output resistance regulator 1 (20-1) may include a resistive circuit having substantially the same resistances as that of the output resistance of the D/A conversion processor 2 (10-2). Also, the D/A conversion processor 2 (10-2) may be configured to include an output voltage regulating circuit which generates a voltage substantially ½^{p} of an output voltage of a resistor ladder circuit by use of a resistance voltage dividing circuit and supplies the voltage to the output resistance regulator 2 (20-2).

The D/A conversion processors 1, 2 (10-1, 10-2) may be configured such that their bit numbers to be converted are identical, i.e., p=q. If the D/A conversion processors 1, 2 (10-1, 10-2) are configured as the resistor string type D/A converter circuit such that p =q, the number of resistors required in the D/A converter circuit 1 is minimized, and thereby the layout area of the D/A converter circuit 1 is minimized.

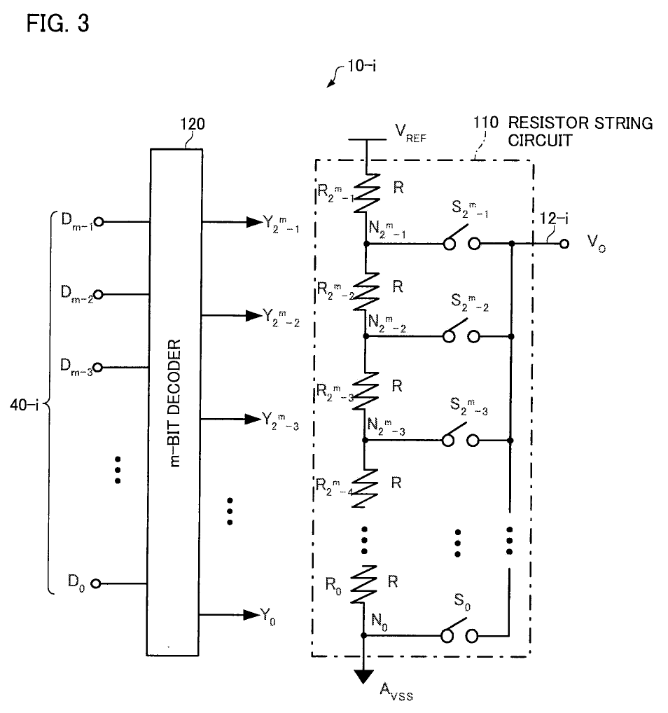

FIG. 3 is a diagram to explain an exemplary configuration of the D/A conversion processor.

A D/A conversion processor i (10-i) is configured as an m-bit D/A converter circuit of the resistor string type (i.e., the case in FIG. 1 where nᵢ=m).

The D/A conversion processor i (10-i) includes a resistor string circuit 110. The resistor string circuit 110 includes serially coupled 2^{m} number of resistors R₀ to R₂^{m}₋₁ and 2^{m} number of switches S₀ to S₂^{m}₋₁. One end of each of the switches S₀ to S₂^{m}₋₁ is coupled to one end of each of the resistors R₀ to R₂^{m}₋₁ by respective nodes N₀ to N₂^{m}₋₁, and the other ends of the switches S₀ to S₂^{m}₋₁ are coupled together to form an output end for outputting a voltage V_{O}. The resistors R₀to R₂^{m-1} have an identical resistance value R. One end of the resistor R₂^{m}₋₁ receives a reference voltage V_{REF}, and one end of the resistor R₀ is connected to analog ground A_{VSS}.

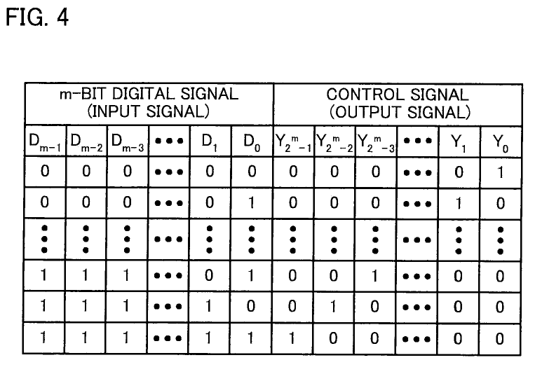

The D/A conversion processor i (10-i) includes an m-bit decoder (a decode circuit) 120. The m-bit decoder 120 decodes m-bit digital signals Dₘ₋₁ to D₀ and generates 2^{m} number of control signals Y₀ to Y₂^{m}₋₁ which control ON/OFF of the respective 2^{m} number of switches S₀ to S₂^{m}₋₁ included in the resistor string circuit 110. If a control signal Yⱼ is 1 (j being any of 0 to 2^{m}₋₁), a switch Sⱼ is turned ON, and if the control signal Yⱼ is 0, the switch Sⱼ is turned OFF. FIG. 4 is a truth table of the control signals Y₀ to Y₂^{m}₋₁ outputted from the m-bit decoder 120. Referring to FIG. 4, the m-bit decoder 120 decodes, in accordance with the values of the m-bit digital signals D₋₁ to D₀, so that only one of the control signals Y₀ to Y₂^{m}₋₁ becomes 0 and all the other control signals become 1. For example, when Dₘ₋₁ to D₀ are all 0, only the control signal Y₀ becomes 1. Thus, only the switch S₀ is turned ON, and the switches S₁ to S₂^{m}₋₁ are turned OFF.

When the switch Sⱼ is ON, an output voltage V₀ becomes V₀=V_{REF}×(j×R)/2^{m}. Thus, the D/A conversion processor i (10-i) operates as the m-bit D/A converter circuit in which Dₘ₋₁ is the most significant bit (MSB).

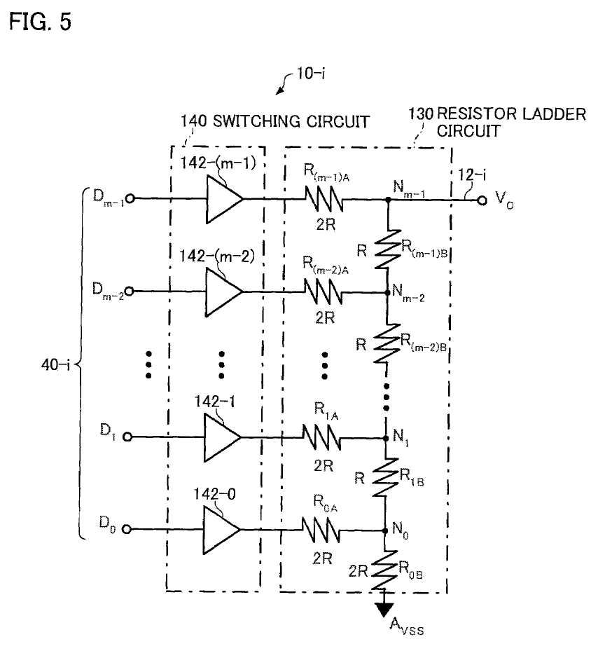

FIG. 5 is a diagram to explain another exemplary configuration of the D/A conversion processor.

The D/A conversion processor i (10-i) is configured as the R-2R resistor ladder type m-bit D/A converter circuit (i.e. a case where nⱼ=m).

The D/A conversion processor i (10-i) includes a resistor ladder circuit 130. The resistor ladder circuit 130 is configured in a manner that the resistors having resistance values R and the resistors having resistance values 2R are coupled in a ladder like fashion. Specifically, a resistor R(_{m-1)A} (resistance value 2R) is coupled to a resistor R(_{m-1)B} (resistance value R) by a node Nₘ₋₁, and a resistor R(_{m-2)A} (resistance value 2R) and a resistor R(_{m-2)B} (resistance value R) are coupled to the resistor R(_{m-1)B} by a node Nₘ₋₂. The other resistors are coupled likewise, up to a resistor R_{1A} (resistance value 2R) and a resistor R_{1B} (resistance value R) which are coupled to a resistor R_{2B} by a node N₁, and a resistor R_{OA} (resistance value 2R) and a resistor R_{0B} (resistance value 2R) which are coupled to a resistor R_{1B} by a node N₀. The other end of a resistor R_{0B} is coupled to analog ground A_{VSS}. The voltage of the node Nₘ₋₁ becomes the output voltage V_{O} of the D/A conversion processor i (10-i).

The D/A conversion processor i (10-i) includes a switching circuit 140. The switching circuit 140 switches the connection of the resistor ladder circuit 130 in accordance with the 4-bit digital signals Dₘ₋₁ to D₀. The switching circuit 140 includes m number of buffers (or other types of switching elements) 142-0 to 142-(m−1). The outputs of the buffers 142-0 to 142-(m−1) are coupled to one ends of the respective resistors R_{OA} to R(_{m-i)A} constituting the resistor ladder circuit 130. The buffers 142-0 to 142-(ₘ₋₁) output A_{VSS} when the respective digital signals Dₘ₋₁ to D₀ are 0 and output V_{REF} when the respective digital signals Dₘ₋₁ to D₀ are 1.

The output voltage V_{O} becomes V_{O}=V_{REF}×(Dₘ₋₁×(½)+Dₘ₋₂×(½²)+ . . . +D₁×(½^{m-1})+D₀×(½^{m})) depending on the digital signals Dₘ₋₁ to D₀. Thus, the D/A conversion processor i (10-i) operates as the m-bit D/A converter circuit in which Dₘ₋₁ is MSB.

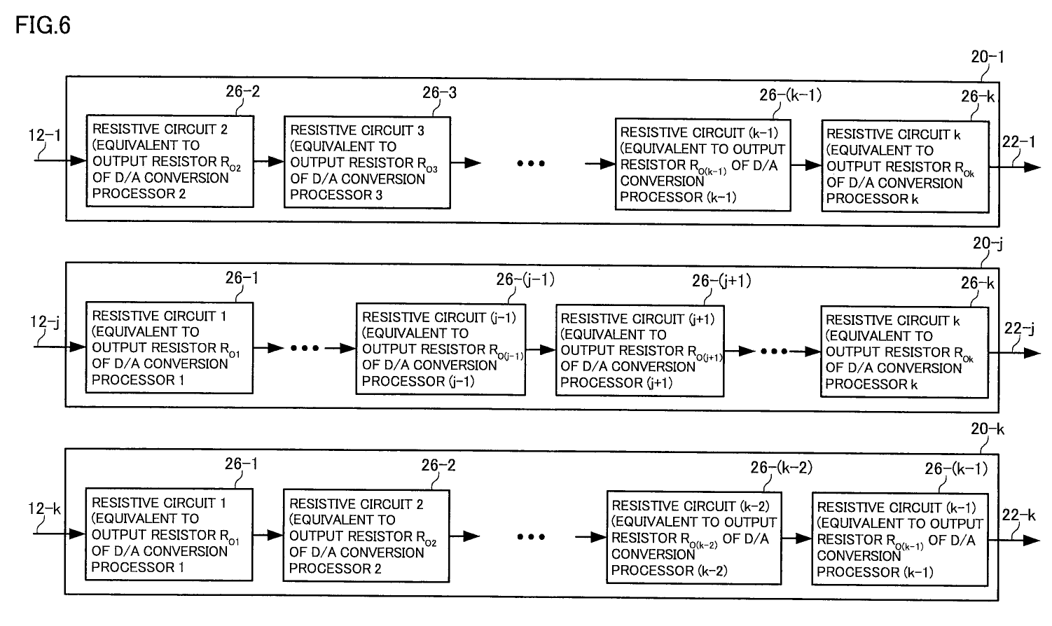

FIG. 6 is an exemplary functional block diagram of the output resistance regulators.

The output resistance regulator 1 (20-1) includes serially coupled k−1 number of resistive circuits 2 to k (26-2 to 26-k).

The output resistance regulator j (20-j) (j being 2 to k−1) includes serially coupled k−1 number of resistive circuits 1 to (j−1) (26-1 to 26-(j−1)) and (j+1) to k (26-(j+1) to 26-k).

The output resistance regulator k (20-k) includes serially coupled k−1 number of resistive circuits 1 to (k−1) (26-1 to 26-(k−1)).

The resistive circuits 1 to k (26-1 to 26-k) are resistive circuits equivalent to the output resistors R_{O1} to R_{Ok} of the respective D/A conversion processors 1 to k.

The output resistance value of the resistor string type m-bit D/A conversion processor as described with reference to FIG. 3 varies in accordance with an m-bit input code. For example, if the resistance value of all of the resistors constituting the resistor string circuit is R, the output resistance of the resistor string type m-bit D/A converter circuit forms a parallel resistance of a resistor having the resistance value of (2^{m}−D)×R and a resistor having the resistance value of D×R, where D is a value obtained by decimally converting the m-bit input code (Dₘ₋₁, Dₘ₋₂, to D₀). Accordingly, the output resistance value R_{O} of the resistor string type m-bit converter circuit becomes R_{O}=R×(D×(2^{m}−D))/2^{m}, and thus the output resistance R_{O} changes in accordance with the input code.

Consequently, if the output voltage V_{OUT} of the D/A converter circuit 1 is generated directly from the output signals 12-1 to 12-k of the D/A conversion processors 1 to k (10-1 to 10-k) when at least one of the D/A conversion processors 1 to k (10-1 to 10-k) is configured as the resistor string type D/A converter circuit, accurate conversion results may not be outputted.

Therefore, with the D/A converter circuit 1, the fluctuation of the output resistance of the resistor string type D/A converter circuit is cancelled by the output resistance regulators having the structure as shown in FIG. 6. Specifically, if the D/A conversion processor i (10-i) (i being any of 1 to k) is configured as the resistor string type D/A converter circuit, every output resistance regulator, except for an output resistance regulator i (20-i) coupled to the D/A conversion processor i (10-i), includes a resistive circuit i (26-i) equivalent to an output resistance R_{Oi} of the D/A conversion processor i (10-i). Thus, the fluctuation of the output resistance of the D/A conversion processor i (10-i) is cancelled.

Also, for example, even if the D/A converter circuit 1 includes three D/A conversion processors 1 to 3 (10-1 to 10-3) (all of which being the resistor string type D/A converter circuits): the output resistance regulator 1 (20-1) with reference to the structure of FIG. 6 includes the resistive circuits 2, 3 (26-2, 26-3) which are equivalent to the output resistors R_{O2}, R_{O3} of the respective D/A conversion processors 2, 3 (10-2, 10-3); the output resistance regulator 2 (20-2) includes the resistive circuits 1, 3 (26-1, 26-3) which are equivalent to the output resistors R_{O1}, R_{O3} of the respective D/A conversion processors 1, 3 (10-1, 10-3); and the output resistance regulator 3 (20-3) includes the resistive circuits 1, 2 (26-1, 26-2) which are equivalent to the output resistors R_{O1}, R_{O2} of the respective D/A conversion processors 1, 2 (10-1, 10-2). Therefore, it is possible to cancel all the fluctuations of the output resistances of the D/A conversion processors 1 to 3 (10-1 to 10-3).

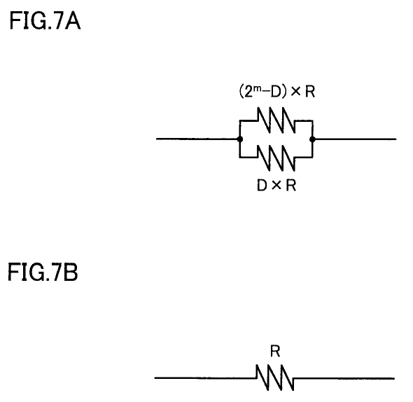

If the D/A conversion processor i (10-i) (i being any of 1 to k) is configured as the resistor string type D/A converter circuit, the resistive circuit i (26-i) may be configured as the resistive circuit as shown in FIG. 7A. The resistive circuit i (26-i) may have the same circuitry configuration as that of the resistor string circuit of the D/A conversion processor i (10-i).

In contrast, the output resistance of the R-2R resistor ladder type m-bit D/A converter circuit as described with reference to FIG. 5 is the constant value R regardless of the m-bit input code (Dₘ₋₁, Dₘ₋₂, to D₀). Therefore, for example, if the D/A conversion processor i (10-1) (i being any of 1 to k) is configured as the R-2R resistor ladder type D/A converter circuit, the resistive circuit 26-i may be configured as the resistive circuit as shown in FIG. 7B.

With reference to the structure of FIG. 6, because the output resistance regulator i (20-i) includes all the resistive circuits equivalent to the output resistances of the D/A conversion processors except the D/A conversion processor i (10-i), the output resistance of the D/A conversion processor i (10-i) and the combined internal resistance of the output resistance regulator i (20-i) (output resistance as observed from the output signal generator 30) have all the same value. Therefore, as described with reference to FIG. 2, by configuring the D/A conversion processors 1 to k (10-1 to 10-k) so that the scale of Vⱼ (j=2 to k) becomes ½^{(n1+ . . . +nj-1)} of the scale of V₁, the output signal generator 30 is configured as a circuit that couples the outputs of the output resistance regulators 1 to k (20-1 to 20-k).

2. First Exemplary D/A Converter Circuit

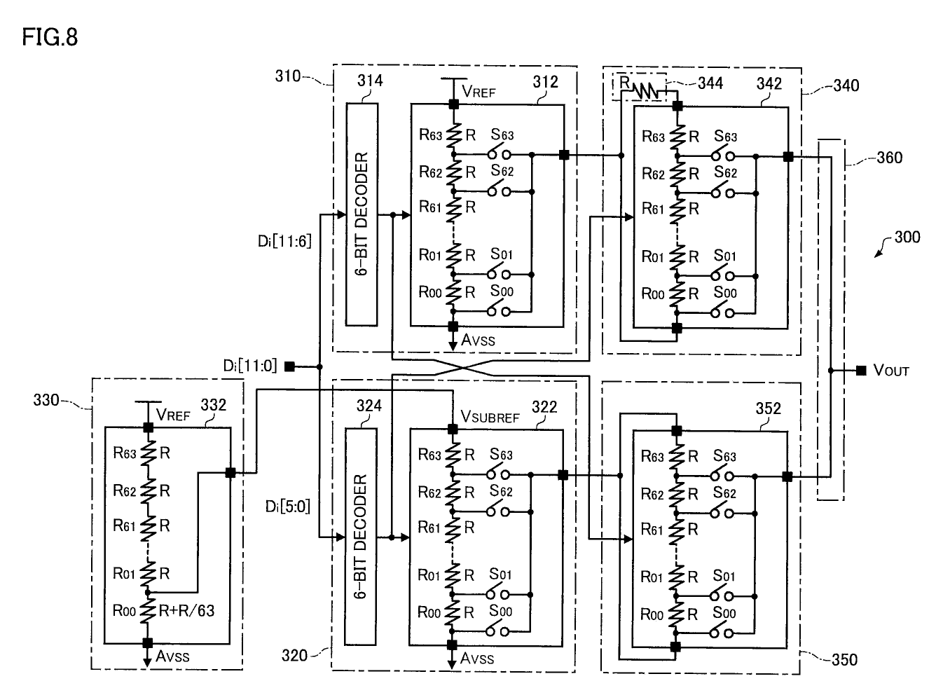

FIG. 8 is a diagram to explain the configuration of the first exemplary D/A converter circuit according to the embodiment of the invention.

A D/A converter circuit 300 is a 12-bit converter circuit that converts a 12-bit input code Dᵢ[11:0] into the output voltage V_{OUT}.

An upper-bit D/A converter circuit 310 is configured as the resistor string type D/A converter circuit which includes a resistor string circuit 312 having 64 resistors (resistance value R) and a 6-bit decoder 314. This circuit 310 performs the D/A conversion of an upper 6-bit code Dᵢ[11:6].

A lower-bit D/A converter circuit 320 is configured as the resistor string type D/A converter circuit which includes a resistor string circuit 322 having 64 resistors (resistance value R) and a 6-bit decoder 324. This circuit 320 performs the D/A conversion of a lower 6-bit code Dᵢ[5:0].

A reference voltage generating circuit 330 generates a reference voltage V_{SUBREF} from a resistance voltage dividing circuit 332 and supplies the voltage to the resistor string circuit 322 of the lower-bit D/A converter circuit 320. The resistance voltage dividing circuit 332 includes serially-coupled 63 resistors of resistance value R and a resistor of resistance value R+R/63. The reference voltage V_{SUBREF}, expressed as V_{SUBREF}=V_{REF}×(R+R/63)/(64R+R/63)≈V_{REF}/64, is approximately ½⁶ of the reference voltage V_{REF} supplied to the resistor string circuit 312 of the upper-bit D/A converter circuit 310. Thus, the scale of the output voltage of the lower-bit D/A converter circuit 320 is ½⁶ of the scale of the output voltage of the upper-bit D/A converter circuit 310. Accordingly, as mentioned above, an output voltage generating circuit 360 may be configured as a circuit for coupling the output of an upper-bit output resistance regulating circuit 340 to the output of a lower-bit output resistance regulating circuit 350.

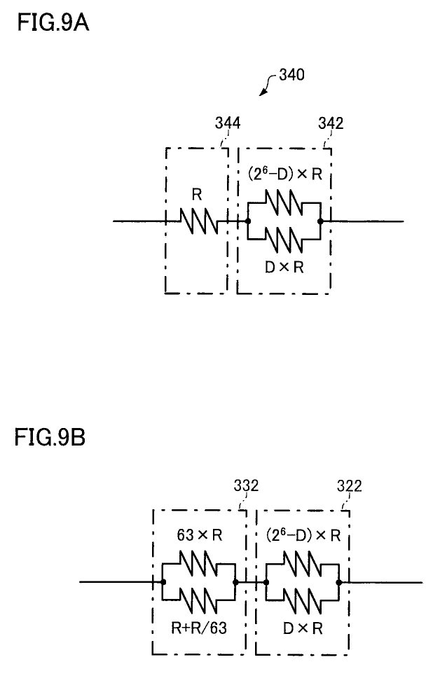

The upper-bit output resistance regulating circuit 340 includes a variable resistance circuit 342 and a resistive circuit 344. The variable resistance circuit 342 is a circuit having the same configuration as that of the resistor string circuit 322 of the lower-bit D/A converter circuit 320. One end of a resistor R₆₃ and one end of a resistor R₀₀ of the variable resistance circuit 342 are coupled to the resistive circuit 344. In addition, the control signal generated by the 6-bit decoder 324 of the lower-bit D/A converter circuit 320 controls the ON/OFF of the 64 switches included in the variable resistance circuit 342. Therefore, the upper-bit output resistance regulating circuit 340 may be represented by the equivalent circuit with reference to FIG. 9A. In FIG. 9A, D indicates a value obtained by decimally converting the lower 6-bit code Dᵢ[5:0].

In contrast, the output resistance of the resistor string circuit 322 of the lower-bit D/A converter circuit 320 and the output resistance of the resistance voltage dividing circuit 332 of the reference voltage generating circuit 330 are represented by an equivalent circuit of FIG. 9B. Referring the equivalent circuits of FIGS. 9A and 9B, the internal resistance of the variable resistance circuit 342 and the output resistance of the resistor string circuit 322 maintain a constant value, regardless of the lower 6-bit code Dᵢ[5:0]. Also, referring to the equivalent circuit of FIG. 9B, because the output resistance of the resistance voltage dividing circuit 332 forms a parallel resistance of a resistor having the resistance of 63×R and a resistor having the resistance of R+R/63, the value of the output resistance of the circuit 332 is substantially equal to R. In other words, the resistance R of the resistive circuit 344 is substantially equal to the resistance of the reference voltage generating circuit 330 (the resistance voltage dividing circuit 332). Ultimately, the internal resistance of the upper-bit output resistance regulating circuit 340 becomes substantially equal to a combined output resistance of the lower-bit D/A converter circuit 320 and the reference voltage generating circuit 330.

The lower-bit output resistance regulating circuit 350 includes a variable resistance circuit 352. The variable resistance circuit 352 is a circuit having the same configuration as that of the resistor string circuit 312 of the upper-bit D/A converter circuit 310. One end of a resistor R₆₃ of the variable resistance circuit 352 and one end of a resistor R₀₀ of the variable resistance circuit 342 are coupled to each other. In addition, the control signal generated by the 6-bit decoder 314 of the upper-bit D/A converter circuit 310 controls ON/OFF of the 64 switches included in the variable resistance circuit 352. Thus, the internal resistance of the lower-bit output resistance regulating circuit 350 becomes substantially equal to the output resistance of the upper-bit D/A converter circuit 310.

As described hereinbefore, the internal resistance of the upper-bit output resistance regulating circuit 340 is substantially equal to the combined output resistance of the lower-bit D/A converter circuit 320 and the reference voltage generating circuit 330, and the internal resistance of the lower-bit output resistance regulating circuit 350 is substantially equal to the output resistance of the upper-bit D/A converter circuit 310. Therefore, the output resistance of the upper-bit output resistance regulating circuit 340 as observed from the output voltage generating circuit 360 and the output resistance of the lower-bit output resistance regulating circuit 350 as observed from the output voltage generating circuit 360 are substantially the same, with only a margin of error that does not influence 1-least significant bit (1LSB) of the 12 bit accuracy.

The D/A converter circuit 300 divides the 12-bit code into exactly half, i.e. upper 6 bits and lower 6 bits, and performs their D/A conversion. Thus, the resistor string circuits 312, 322 and the variable resistance circuits 342, 352 may all have completely the same configuration. Accordingly, the resistor string circuits 312, 322 and the variable resistance circuits 342, 352 may use the same layout pattern.

Out of the 64 serially-coupled resistors in the resistor string circuits 312, 322 and the variable resistance circuits 342, 352, the resistance voltage dividing circuit 332 may be configured by serially-coupling the resistor of resistance value R/63 between the resistor R₀₀ (resistance value R) and analog ground A_{VSS}. Accordingly, the resistance voltage dividing circuit 332 is made to have substantially the same layout pattern as those of the resistor parts of the resistor string circuits 312, 322 and the variable resistance circuits 342, 352.

As a result, even if the resistors in the resistor string circuits 312, 322, in the variable resistance circuits 342, 352, and in the resistance voltage dividing circuit 332 fluctuate due to manufacturing variations, they fluctuate in the same direction, and it is therefore possible to suppress the deterioration in D/A conversion accuracy of the D/A converter circuit 300.

Additionally, the D/A converter circuit 300 is configured such that the number of resistors in the resistor string circuits 312, 322 is minimized when the 12-bit code is divided into two, i.e. divided exactly in half into upper 6 bits and lower 6 bits. As a consequence, the number of resistors in the variable resistance circuits 342, 352 is also minimized. Thus, the D/A converter circuit 300 is practically sized and made to perform the D/A conversion process with 12-bit conversion accuracy while using two resistor string type D/A converter circuits.

According to the D/A converter circuit 300 of the embodiment of the invention, the upper-bit D/A converter circuit 310 (the first D/A conversion processor) configured as the resistor string type D/A converter circuit performs the conversion of the upper 6 bits (Dᵢ[11:6]) obtained by dividing the 12 bits of digital signal Dᵢ[11:0] into two. Because the resistor string type D/A converter circuit performs the conversion process, the conversion accuracy of ½⁶ required for the upper 6-bit D/A conversion is secured.

Also, according to the D/A converter circuit 300 of the embodiment of the invention, the lower-bit output resistance regulating circuit 350 (the second output resistance regulator), which is coupled to the lower-bit D/A converter circuit 320 (the second D/A conversion processor) that converts the lower 6-bits (Dᵢ[5:0]), includes the variable resistance circuit 352 that changes the resistance value to be equal to the output resistance value of the upper-bit D/A converter circuit 310 (the resistor string type D/A converter circuit). It is therefore possible to suppress the deterioration in D/A conversion accuracy due to fluctuation of the output resistance of the resistor string type D/A converter circuit.

Moreover, according to the D/A converter circuit 300 of the embodiment of the invention, the variable resistance circuit 352 of the lower-bit output resistance regulating circuit 350 has the same configuration as that of the resistor string circuit 312 of the upper-bit D/A converter circuit 310. Therefore, the resistance of the lower-bit output resistance regulating circuit 350 may readily be substantially equal to the output resistance of the upper-bit D/A converter circuit 310.

Furthermore, according to the D/A converter circuit 300 of the embodiment of the invention, because the variable resistance circuit 352 of the lower-bit output resistance regulating circuit 350 has the same configuration as that of the resistor string circuit 312 of the upper-bit D/A converter circuit 310, the same layout pattern may be used. Therefore, because the fluctuation of the resistance due to manufacturing variations is cancelled, it is possible to provide the D/A converter circuit with higher performance.

Also, according to the D/A converter circuit 300 of the embodiment of the invention, not only the upper-bit D/A converter circuit 310 but also the lower-bit D/A converter circuit 320 is configured as the resistor string type D/A converter circuit. Therefore, because the lower-bit D/A converter circuit 320 may secure the conversion accuracy of ½⁶, the conversion accuracy of ½¹² as a whole may be secured.

Moreover, according to the D/A converter circuit 300 of the embodiment of the invention, the upper-bit output resistance regulating circuit 340 (the first output resistance regulator) coupled to the output of the upper-bit D/A converter circuit 310 includes the variable resistance circuit 342 that changes the resistance value to be equal to the output resistance value of the lower-bit D/A converter circuit 320 (the resistor string type D/A converter circuit). It is therefore possible to suppress the deterioration in D/A conversion accuracy of the D/A converter circuit due to fluctuation of the output resistance of the resistor string type D/A converter circuit.

Furthermore, according to the D/A converter circuit 300 of the embodiment of the invention, the variable resistance circuit 342 of the upper-bit output resistance regulating circuit 340 has the same configuration as that of the resistor string circuit 322 of the lower-bit D/A converter circuit 320. Therefore, the resistance of the upper-bit output resistance regulating circuit 340 may readily be substantially equal to the resistance of the output resistance of the lower-bit D/A converter circuit 320.

Also, according to the D/A converter circuit 300 of the embodiment of the invention, because the variable resistance circuit 342 of the upper-bit output resistance regulating circuit 340 has the same configuration as that of the resistor string circuit 322 of the lower-bit D/A converter circuit 320, the same layout pattern may be used. Therefore, because the fluctuation of the resistance value due to manufacturing variation is cancelled, it is possible to provide the D/A converter circuit with higher performance.

Moreover, according to the D/A converter circuit 300 of the embodiment of the invention, the resistor string circuit 322 of the lower-bit D/A converter circuit 320 receives ½⁶ of the reference voltage V_{REF} that is supplied to the resistor string circuit 312 of the upper-bit D/A converter circuit 310. Therefore, the scale of the output voltage of the lower-bit D/A converter circuit 320 becomes ½⁶ of the scale of the output voltage of the upper-bit D/A converter circuit 310. For this reason, circuits for adjusting the output voltage of the lower-bit D/A converter circuit 320 are not required.

Furthermore, according to the D/A converter circuit 300 of the embodiment of the invention, the upper-bit output resistance regulating circuit 340 includes not only the variable resistance circuit 342 that changes the resistance value to be equal to the output resistance value of the lower-bit D/A converter circuit 320 but also the resistive circuit 344 having the resistance R substantially equal to the output resistance of the reference voltage generating circuit 330 (the reference voltage supply section). Accordingly, the output resistances of the upper-bit output resistance regulating circuit 340 and the lower-bit output resistance regulating circuit 350, as observed from the output voltage generating circuit 360 (the output signal generator), may be made substantially the same. Therefore, it is possible to provide the D/A converter circuit with higher performance.

Additionally, according to the D/A converter circuit 300 of the embodiment of the invention, because the upper-bit and lower-bit D/A converter circuits 310, 320 are configured such that the upper-bit and lower-bit numbers p, q are equally (n/2), it is possible to use the resistor string type D/A converter circuits having completely the same circuitry configuration. Further, the configurations of the upper-bit and lower-bit output resistance regulating circuits 340, 350 may also be made the same as those of the upper-bit and lower-bit D/A converter circuits 310, 320. This means that, because all these circuits 340, 350, 310, 320 may have the same configuration, they may use the same layout pattern. Therefore, the fluctuation of the resistance value due to manufacturing variations is cancelled, and it is possible to provide the D/A converter circuit with higher performance.

3. Second Exemplary D/A Converter Circuit

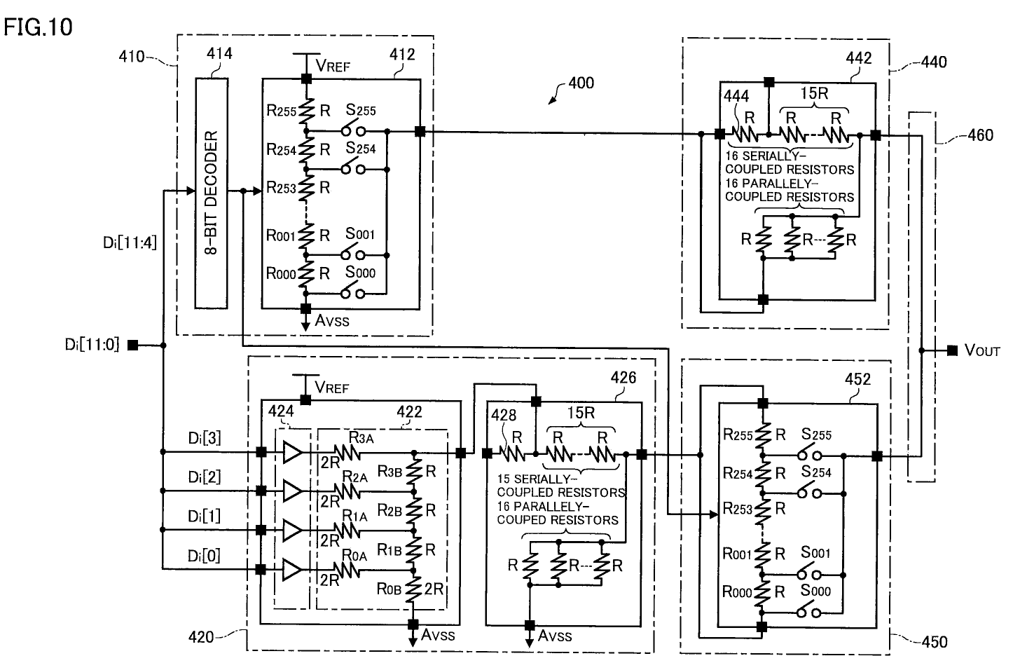

FIG. 10 is a diagram to explain the configuration of the second exemplary D/A converter circuit according to the embodiment of the invention.

The D/A converter circuit 400 is a 12-bit D/A converter circuit that converts a 12-bit input code Dᵢ[11:0] into an output voltage V_{OUT}.

An upper-bit D/A converter circuit 410 is configured as the resistor string type D/A converter circuit which includes a resistor string circuit 412 having 256 resistors (resistance value R) and an 8-bit decoder 414. This circuit 410 performs the D/A conversion of an upper 8-bit code Dᵢ[11:4].

A lower-bit D/A converter circuit 420 is configured as the R-2R resistor ladder type D/A converter circuit which includes: a resistor ladder circuit 422 having 3 resistors of resistance value R and 5 resistors of resistance value 2R, a switching circuit 424 having 4 buffers, and an output voltage regulating circuit 426. This circuit 420 performs the D/A conversion of a lower 4-bit code Dᵢ[3:0].

The resistor string circuit 412 of the upper-bit D/A converter circuit 410, the resistor ladder circuit 422 of the lower-bit D/A converter circuit 420, and the switching circuit 424 operate at the same reference voltage V_{REF}. Thus, the scale of the output voltage of the resistor string circuit 412 is equal to the scale of the output voltage of the resistor ladder circuit 422. The output voltage regulating circuit 426 is thus incorporated in order to adjust the output voltage of the resistor ladder circuit 422 to approximately ½⁸.

In the output voltage regulating circuit 426, 15 serially-coupled resistors (resistance value R) and 16 parallelly-coupled resistors (resistance value R) are serially coupled between the output of the resistor ladder circuit 422 and A_{VSS}. The output resistance of the resistor ladder circuit 422 is the constant value R regardless of the input code Dᵢ[3:0]. Therefore, after being divided by the output resistance (resistance value R) of the resistor ladder circuit 422, the 15 serially-coupled resistors (resistance value R), and by the 16 parallelly-coupled resistors (resistance value R), the output voltage of the output voltage regulating circuit 426 becomes approximately ½⁸ of the output voltage of the resistor ladder circuit 422.

An upper-bit output resistance generating circuit 440 includes a resistive circuit 442. The resistive circuit 442 has the same configuration as that of the output voltage regulating circuit 426, except that a resistor 444 having the resistance value R is added. The resistor 444 is added so as to cancel the value of the output resistance R of the resistor ladder circuit 422. Accordingly, the internal resistance of the upper-bit output resistance regulating circuit 440 becomes equal to the output resistance (a combined output resistance of the resistor ladder circuit 422 and the output voltage regulating circuit 426) of the lower-bit D/A converter circuit 420.

A lower-bit output resistance regulating circuit 450 includes a variable resistance circuit 452. The variable resistance circuit 452 is a circuit having the same configuration as that of the resistor string circuit 412 of the upper-bit D/A converter circuit 410. One end of a resistor R₂₅₅ of the variable resistance circuit 452 is coupled to one end of a resistor R₀₀₀. Also, the control signal generated by the 8-bit decoder 414 of the upper-bit D/A converter circuit 410 controls ON/OFF of the 256 switches included in the variable resistance circuit 452. Accordingly, the internal resistance of the lower-bit output resistance regulating circuit 450 becomes equal to the output resistance of the upper-bit D/A converter circuit 410.

As described hereinbefore, the internal resistance of the upper-bit output resistance regulating circuit 440 is equal to the output resistance of the lower-bit D/A converter circuit 420, and the internal resistance of the lower-bit output resistance regulating circuit 450 is equal to the output resistance of the upper-bit D/A converter circuit 410. Therefore, the output resistance of the upper-bit output resistance regulating circuit 440 as observed from the output voltage generating circuit 460 is equal to the output resistance of the lower-bit output resistance regulating circuit 450 as observed from the output voltage generating circuit 460. Also, as stated earlier, the scale of the output voltage of the lower-bit D/A converter circuit 420 becomes approximately ½⁸ of the scale of the output voltage of the upper-bit converter circuit 410. The D/A converter circuit 400 may therefore perform the D/A conversion with the 12-bit accuracy.

The D/A converter circuit 400 performs the D/A conversion of both the upper 8 bits and lower 4 bits which are divided from the 12-bit code. Then, the upper 8-bit D/A conversion requiring the 12-bit accuracy is conducted by the resistor string type D/A converter circuit, and the lower 4-bit D/A conversion requiring only the 4-bit accuracy is conducted by the R-2R resistor ladder type D/A converter circuit having a small layout area. Thus, the D/A converter circuit 400 is sized practically but made to perform the D/A conversion process with the 12-bit conversion accuracy.

Also, in the D/A converter circuit 400, the resistor string circuit 412 and the variable resistance circuit 452 have completely the same configuration. Thus, these circuits 412, 452 may use the same layout pattern. Moreover, a dummy resistor 428 having the resistance R is disposed in the output voltage regulating circuit 426 so that the output voltage regulating circuit 426 and the resistive circuit 442 have the same layout pattern. As a result, even if the resistances of the resistor string circuit 412, the variable resistance circuit 452, the output voltage regulating circuit 426, and of the resistive circuit 442 fluctuate due to manufacturing variations, they fluctuate in the same direction, and it is therefore possible to suppress the deterioration in D/A conversion accuracy of the D/A converter circuit 400.

According to the D/A converter circuit 400 of the embodiment of the invention, the upper-bit D/A converter circuit 410 (the first D/A conversion processor) configured as the resistor string type D/A converter circuit performs the conversion of the upper 8 bits (Dᵢ[11:4]) obtained by dividing the 12-bit digital signal Dᵢ[11:0] into two. Because the resistor string type D/A converter circuit performs the conversion process, the conversion accuracy of ½⁸ required for the upper 8-bit D/A conversion is secured.

Also, according to the D/A converter circuit 400 of the embodiment of the invention, the lower-bit output resistance regulating circuit 450 (the second output resistance regulator), which is coupled to the lower-bit D/A converter circuit 420 (the second D/A conversion processor) that converts the lower 4-bits (Dᵢ[3:0]), includes the variable resistance circuit 452 which changes the resistance value to be the same as the output resistance value of the upper-bit D/A converter circuit 410 (the resistor string type D/A converter circuit). It is therefore possible to suppress the deterioration in D/A conversion accuracy of the D/A converter circuit due to fluctuation of the output resistance of the resistor string type D/A converter circuit.

Moreover, according to the D/A converter circuit 400 of the embodiment of the invention, the variable resistance circuit 452 of the lower-bit output resistance regulating circuit 450 has the same configuration as that of the resistor string circuit 412 of the upper-bit D/A converter circuit 410. Therefore, the resistance of the lower-bit output resistance regulating circuit 450 may be readily made equal to the output resistance of the upper-bit D/A converter circuit 410.

Furthermore, according to the D/A converter circuit 400 of the embodiment of the invention, because the variable resistance circuit 452 of the lower-bit output resistance regulating circuit 450 and the resistor string circuit 412 of the upper-bit D/A converter circuit 410 have the same configuration, the same layout pattern may be used. Thus, because the fluctuation of the resistance due to manufacturing variations is cancelled, it is possible to provide the D/A converter circuit with higher performance.

Also, according to the D/A converter circuit 400 of the embodiment of the invention, the lower-bit D/A converter circuit 420 is configured as the R-2R resistor ladder type D/A converter circuit. Therefore, compared to the lower-bit D/A converter circuit 420 configured as the resistor string type D/A converter circuit, the layout area of the second D/A conversion processor is reduced.

Moreover, according to the D/A converter circuit 400 of the embodiment of the invention, the lower-bit output resistance regulating circuit 450 coupled to the output of the upper-bit D/A converter circuit 410 includes the resistor 444 having the same resistance as the output resistance R of the lower-bit D/A converter circuit 420 (the R-2R resistor ladder type D/A converter circuit). Therefore, the output resistance R of the R-2R resistor ladder type D/A converter circuit is cancelled.

Additionally, the switching circuit 424 becomes inoperable when ½⁸ of the reference voltage V_{REF} supplied to the upper-bit D/A converter circuit 410 is supplied to the lower-bit D/A converter circuit 420, as in the case with the D/A converter circuit 300 of FIG. 8. However, according to the D/A converter circuit 400 of the embodiment of the invention, the output voltage generating circuit 426 generates approximately ½⁸ of the output voltage of the resistor ladder circuit 422 and supplies this voltage to the lower-bit output resistance regulating circuit 450, and thus the lower-bit D/A converter circuit 420 may carry out the normal D/A conversion process.

b 4. Integrated Circuit Device

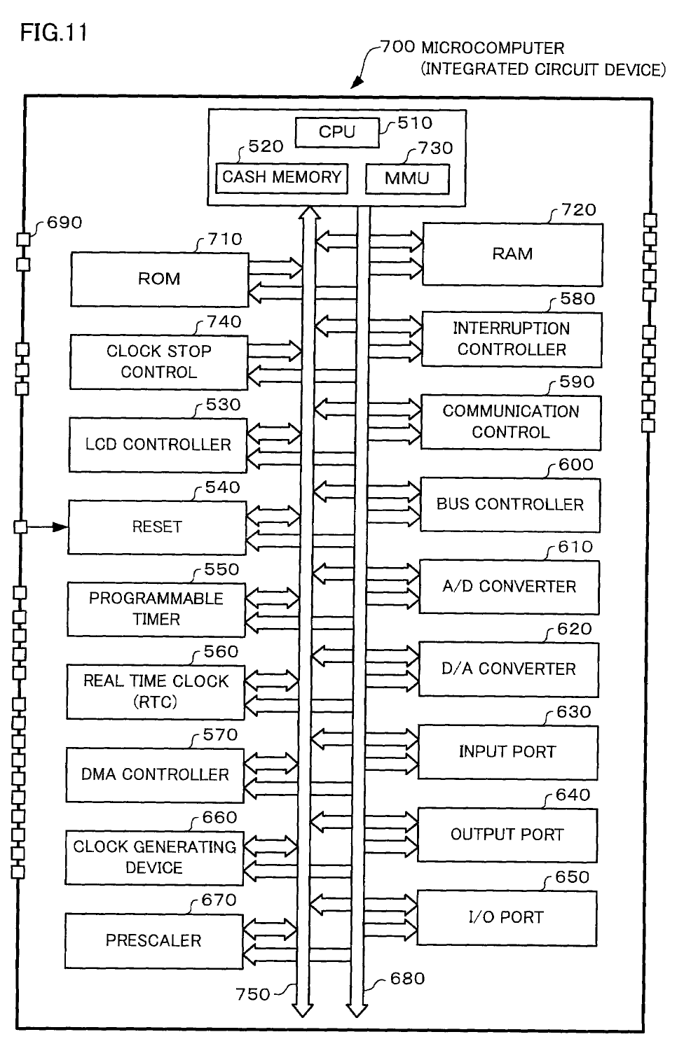

FIG. 11 is an exemplary block diagram of the integrated circuit device according to one embodiment.

A microcomputer (the integrated circuit device) 700 includes: a central processing unit (CPU) 510, a cash memory 520, a read-only memory (ROM) 710, a random access memory (RAM) 720, a memory management unit (MMU) 730, a liquid crystal display (LCD) controller 530, a reset circuit 540, a programmable timer 550, a real time clock (RTC) 560, a direct memory access (DMA) controller 570, an interruption controller 580, a communication control circuit 590, a bus controller 600, an analog-to-digital (A/D) converter 610, a D/A converter 620, an input port 630, an output port 640, an input/output (I/O) port 650, a clock generating device 660, a prescaler 670, and a clock stop control circuit 740. The microcomputer 700 also includes a general-purpose bus 680, a dedicated bus 750, and various types of pins 690 to connect these devices.

The D/A converter 620 is the D/A converter circuit of the embodiment. By incorporating the D/A converter circuit of the embodiment, an integrated circuit device performing the D/A conversion of a relatively large bit number is provided at low costs.

5. Electronic Apparatus

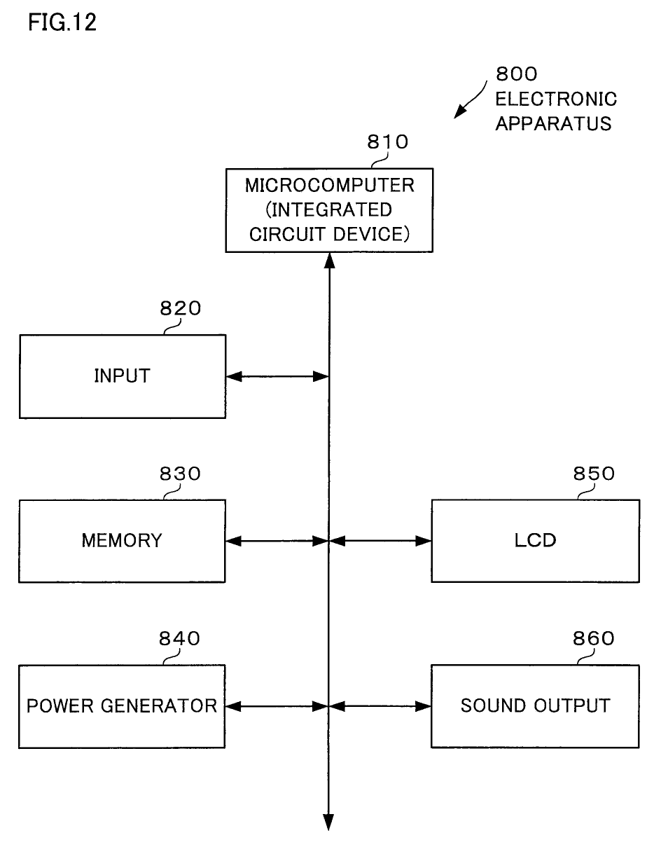

FIG. 12 is an exemplary block diagram of the electronic apparatus of one embodiment. An electronic apparatus 800 includes: a microcomputer (the integrated circuit device) 810, an input section 820, a memory 830, a power generator 840, a liquid crystal display (LCD) 850, and a sound output section 860.

The input section 820 is for inputting various types of data. The microcomputer 810 carries out various processes based on the data inputted by the input section 820. The memory 830 is the work area for the microcomputer 810. The power generator 840 is for generating various types of powers used in the electronic apparatus 800. The LCD 850 is for outputting various images (e.g., letters, icons, graphics) displayed on the electronic apparatus.

The sound output section 860 is for outputting various types of sounds (e.g., voice, game sounds) outputted from the electronic apparatus 800 and is operable by use of hardware such as a speaker.

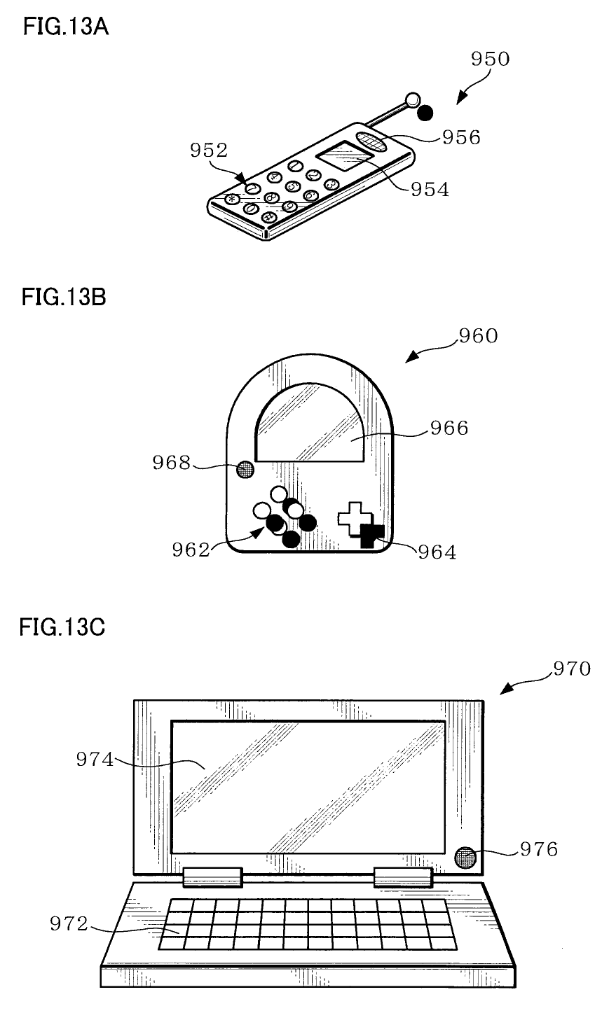

FIG. 13A is an external view of an exemplary mobile phone 950 which is one type of the electronic apparatus. This mobile phone 950 includes: a dial button 952 operating as an input section, an LCD 954 displaying e.g. telephone numbers, names, and icons, and a speaker 956 operating as a sound output section and outputting sounds.

FIG. 13B is an external view of an exemplary mobile type game apparatus 960 which is one type of the electronic apparatus. This mobile type game apparatus 960 includes: a manual operation button 962 operating as an input section, a directional pad (cross-shaped key pad) 964, an LCD 966 displaying game images, and a speaker 968 operating as a sound output section and outputting game sounds.

FIG. 13C is an external view of an exemplary personal computer 970 which is one type of the electronic apparatus. This personal computer 970 includes: a keyboard 972 operating as an input section, an LCD 974 displaying letters, numbers, and graphics, and a sound output section 976.

By incorporating the integrated circuit device of the embodiment in the electronic apparatuses of FIGS. 13A through 13C, high-performance electronic apparatuses are provided at low costs.

Other examples of the electronic apparatus using the embodiment of the invention, in addition to the examples with reference to FIGS. 13A through 13C, are: mobile type information terminals, pagers, desktop electronic calculators, equipment having touch panels, projectors, word processors, view-finder-type and direct-monitor-type videotape recorders, and car navigation systems.

The present invention is not limited to the embodiments of the invention but allows various modifications within the scope of the invention.

For example, in the D/A converter circuit 300 as described with reference to FIG. 8, the 12 bits are divided into the upper 6 bits and lower 6 bits. However, the 12 bits may be divided into any varied number of bits, or they may be divided into three or more. Similarly, in the D/A converter circuit 400 as described with reference to FIG. 10, the 12 bits are divided into the upper 8 bits and lower 4 bits. However, the 12 bits may be divided into any varied number of bits, or they may be divided into three or more.

Also, for example, the D/A converter circuit 300 as described with reference to FIG. 8 may further include an additional circuit, which supplies the reference voltage that is equal to the reference voltage V_{REF} supplied to the resistor string circuit 312 of the upper-bit D/A converter circuit 310, to the resistor string circuit 322 of the lower-bit D/A converter circuit 320 (thereby eliminating the reference voltage generating circuit 330) and adjusts the output voltage of the resistor string circuit 322 of the upper-bit D/A converter circuit 320 to ½⁸.

The invention includes structures that are substantially the same structures (e.g., having the same functions, methods, and results or the same objectives and effects) as those described in the embodiments. Also, the invention includes structures in which non-essential elements of the structures described in the embodiments are substituted for other elements. Moreover, the invention includes structures with which the same operational effects may be produced and the same objectives may be achieved as those with the structures described in the embodiments. Furthermore, the invention includes structures employing known techniques in addition to the structures described in the embodiments.

1. A digital-to-analog (D/A) converter circuit which converts a digital signal of n bits into an analog signal and outputs the analog signal, comprising:
a plurality of D/A conversion processors, each of which converting a digital signal into an analog signal, the digital signal being made by dividing the n-bit digital signal at least into two parts;
a plurality of output resistance regulators coupled to outputs of the plurality of respective D/A conversion processors; and
an output signal generator generating the analog signal that forms an output of the D/A converter circuit based on outputs of the plurality of output resistance regulators, wherein:
at least one of the D/A conversion processors is configured as a resistor string type D/A converter circuit including:
a resistor string circuit which has a plurality of serially-coupled resistors and a plurality of switches, one end of each of the plurality of switches being coupled to one of coupling points of the plurality of resistors, and other ends of the plurality of switches being coupled together to form an output end; and
a decode circuit which decodes the digital signal and generates a control signal that controls ON/OFF of the plurality of switches included in the resistor string circuit, and wherein
each of the plurality of output resistance regulators includes a variable resistance circuit which changes a resistance value to be substantially equal to an output resistance value of the D/A conversion processor, in accordance with a change in the output resistance value of the D/A conversion processor that is coupled to another output resistance regulator and configured as the resistor string type D/A converter circuit.

2. The D/A converter circuit according to claim 1, wherein:
the output signal generator includes a circuit that couples the outputs of the plurality of output resistance regulators.

3. The D/A converter circuit according to claim 1, wherein:
a first one of the plurality of D/A conversion processors is configured as the resistor string type D/A converter circuit that converts a digital signal of upper p bits, out of the n bits, into an analog signal;
a second one of the plurality of D/A conversion processors converts a digital signal of lower q bits, out of the n bits, into an analog signal, wherein q equals n minus p; and
a second one of the plurality of output resistance regulators which is coupled to an output of the second D/A conversion processor includes the variable resistance circuit that changes a resistance value to be substantially equal to an output resistance value of the first D/A conversion processor, in accordance with a change in the output resistance value of the first D/A conversion processor.

4. The D/A converter circuit according to claim 3, wherein:
the variable resistance circuit of the second output resistance regulator has a same configuration as that of the resistor string circuit of the first D/A conversion processor.

5. The D/A converter circuit according to claim 3, wherein:
the second D/A conversion processor is configured as the resistor string type D/A converter circuit; and
a first one of the plurality of output resistance regulators which is coupled to an output of the first D/A conversion processor includes the variable resistance circuit that changes a resistance value to be substantially equal to an output resistance value of the second D/A conversion processor, in accordance with a change in the output resistance value of the second D/A conversion processor.

6. The D/A converter circuit according to claim 5, wherein:
the variable resistance circuit of the first output resistance regulator has a same configuration as that of the resistor string circuit of the second D/A conversion processor.

7. The D/A converter circuit according to claim 5, further comprising:
a reference voltage supply section which, by use of a first resistance voltage dividing circuit, generates substantially ½^{p} of a reference voltage supplied to the resistor string circuit of the first D/A conversion processor and supplies the voltage to the resistor string circuit of the second D/A conversion processor.

8. The D/A converter circuit according to claim 7, wherein:
the first output resistance regulator further includes a resistive circuit having a resistance value substantially equal to an output resistance value of the reference voltage supply section.

9. The D/A converter circuit according to claim 3, wherein:
the second D/A conversion processor is configured as an R-2R resistor ladder type D/A converter circuit including:
a resistor ladder circuit having a resistor of a resistance value R and a resistor of a resistance value 2R that are connected in a ladder like fashion; and
a switching circuit switching the connection of the resistor ladder circuit in accordance with the digital signal, and wherein
the first output resistance regulator that is coupled to an output of the first D/A conversion processor and includes a resistive circuit having a resistance value substantially equal to an output resistance value of the second D/A conversion processor.

10. The D/A converter circuit according to claim 9, wherein:
the second D/A conversion processor includes an output voltage regulating circuit which, by use of a second resistance voltage dividing circuit, generates substantially ½^{p} of an output voltage of the resistor ladder circuit and supplies the voltage to the second output resistance regulator.

11. The D/A converter circuit according to claim 3, wherein p=q.

12. An integrated circuit device comprising the D/A converter circuit according to claim 1.

13. An electronic apparatus, comprising:
the integrated circuit device according to claim 12;
an input section that receives input information; and
an output section that, based on the input information, outputs a result processed by the integrated circuit device.

14. The D/A converter circuit according to claim 4, wherein p=q.

15. The D/A converter circuit according to claim 5, wherein p=q.

16. The D/A converter circuit according to claim 6, wherein p=q.

17. The D/A converter circuit according to claim 7, wherein p=q.

18. The D/A converter circuit according to claim 8, wherein p=q.

19. The D/A converter circuit according to claim 9, wherein p=q.

20. The D/A converter circuit according to claim 10, wherein p=q.
